(19) United States
(12) Patent Application Publication
(10) Pub. No.: US 2026/0136648 A1
(43) Pub. Date: May 14, 2026

(54) SEMICONDUCTOR DEVICE

(71) Applicant: SUMITOMO ELECTRIC INDUSTRIES, LTD., Osaka (JP)

(72) Inventor: Harutoshi TSUJI, Osaka (JP)

(21) Appl. No.: 19/375,569

(22) Filed: Oct. 31, 2025

(30) Foreign Application Priority Data
Nov. 14, 2024 (JP) 2024-199295

(51) Int. Cl. H10D 84/80; H01L 23/00; H01L 23/66; H03F 3/193; H03H 7/38

(52) U.S. Cl. CPC H10D 84/811; H03F 3/193; H03H 7/38; H10W 44/20; H10W 44/234; H10W 90/758

(57) ABSTRACT

A semiconductor device includes a semiconductor chip having a substrate, units arranged in an array direction, each including a FET having gate, source, and drain electrodes on the substrate, and a gate pad to which the gate electrode is electrically connected; an input terminal to which a high-frequency signal is input; and a matching circuit including bonding wires electrically connected between the input terminal and the gate pad, each having a first end bonded to a respective one of regions in the gate pad. The units include first and second units, and the first unit is closer to a center of the units in the array direction, and includes a first capacitive element electrically connected between the gate pad and a reference potential. The second unit includes no capacitive element or a second capacitive element having a smaller capacitance value, electrically connected between the gate pad and the reference potential.

### CROSS REFERENCE TO RELATED APPLICATIONS

This application is based on and claims priority to Japanese Patent Application No. 2024-199295 filed on Nov. 14, 2024, the entire contents of which are incorporated herein by reference.

### TECHNICAL FIELD

The present disclosure relates to a semiconductor device.

### BACKGROUND

In a semiconductor device used in a high-frequency circuit, it is known that a plurality of bonding wires are bonded to a pad of a semiconductor chip provided with a transistor in a direction in which the pad extends, and the bonding wires are used as a part of a matching circuit (for example, Japanese Unexamined Patent Application Publication No. 2014-96497).

### SUMMARY

An embodiment according to the present disclosure is a semiconductor device that includes a semiconductor chip including a substrate, a plurality of units arranged in an array direction, each of the plurality of units including a unit FET having a gate electrode, a source electrode, and a drain electrode provided on the substrate, and a gate pad to which the gate electrode of each of the plurality of units is electrically connected and that extends in the array direction and is provided on the substrate; an input terminal to which a high-frequency signal is input; and a matching circuit including a plurality of bonding wires electrically connected between the input terminal and the gate pad, each of the plurality of bonding wires having a first end bonded to a respective one of a plurality of regions arranged in the array direction in the gate pad. The plurality of units include a first unit and a second unit, and the first unit is closer to a center of the plurality of units in the array direction than the second unit is. The first unit includes a first capacitive element electrically connected between the gate pad and a reference potential. The second unit includes no capacitive element electrically connected between the gate pad and the reference potential, or includes a second capacitive element electrically connected between the gate pad and the reference potential and having a capacitance value smaller than a capacitance value of the first capacitive element.

An embodiment according to the present disclosure is a semiconductor device including a substrate; a plurality of units arranged in an array direction on the substrate, each of the plurality of units including a unit FET having a gate electrode, a source electrode, and a drain electrode; and a gate pad to which the gate electrode of each of the plurality of units is electrically connected and that extends in the array direction and is provided on the substrate. The plurality of units include a first unit and a second unit, and the first unit is closer to a center of the plurality of units in the array direction than the second unit is. The first unit includes a first capacitive element electrically connected between the gate pad and a reference potential. The second unit includes no capacitive element electrically connected between the gate pad and the reference potential, or includes a second capacitive element electrically connected between the gate pad and the reference potential and having a capacitance value smaller than a capacitance value of the first capacitive element.

### BRIEF DESCRIPTION OF THE DRAWINGS

FIG. 1 is a circuit diagram of a semiconductor device according to a first embodiment.

FIG. 2 is a plan view of the semiconductor device according to the first embodiment.

FIG. 3 is a plan view of a semiconductor chip in the first embodiment.

FIG. 4 is a cross-sectional view taken along line A-A in FIG. 3.

FIG. 5 is a cross-sectional view taken along line B-B in FIG. 3.

FIG. 6 is an equivalent circuit diagram of the semiconductor device according to the first embodiment.

FIG. 7 is a plan view illustrating a part of a semiconductor chip in a simulation.

FIG. 8 is a Smith chart illustrating an impedance Zin versus a frequency in a sample A.

FIG. 9 is a graph illustrating an amplitude of impedance Zin versus a frequency in the sample A.

FIG. 10 is a graph illustrating a phase of impedance Zin versus a frequency in the sample A.

FIG. 11 is a graph illustrating an amplitude of impedance Zin versus a unit number at 2f0 (7.6 GHz) in the sample A.

FIG. 12 is a graph illustrating a phase of impedance Zin versus a unit number at 2f0 (7.6 GHz) in the sample A.

FIG. 13 is a graph illustrating a capacitance value added to each unit in a sample B.

FIG. 14 is an expanded view of the Smith chart illustrating an impedance Zin versus a frequency in the sample A.

FIG. 15 is an expanded view of a Smith chart illustrating an impedance Zin versus a frequency in the sample B.

FIG. 16 is a graph illustrating an amplitude of impedance Zin versus a unit number in the samples A and B.

FIG. 17 is a graph illustrating a phase of impedance Zin versus a unit number in the samples A and B.

FIG. 18 is a graph illustrating a capacitance value added to each unit in a sample C.

FIG. 19 is a graph illustrating an amplitude of impedance Zin versus a unit number in the samples A and C.

FIG. 20 is a graph illustrating a phase of impedance Zin versus a unit number in the samples A and C.

FIG. 21 is a graph illustrating a capacitance value added to each unit in a sample D.

FIG. 22 is a graph illustrating an amplitude of impedance Zin versus a unit number in the samples A and D.

FIG. 23 is a graph illustrating a phase of impedance Zin versus a unit number in the samples A and D.

### DETAILED DESCRIPTION

In a transistor in which a plurality of unit FETs are arranged in an array direction, a pad is elongated in the array direction. In this case, an impedance as viewed from a unit FET located at the center of the transistor in the array direction to a matching circuit may be different from an impedance as viewed from a unit FET located at an end of the transistor in the array direction to the matching circuit. This degrades characteristics of the transistor.

According to the present disclosure, the characteristics of the semiconductor device can be improved.

### Description of Embodiments of the Present Disclosure

First, embodiments of the present disclosure will be listed and described.
(1) An embodiment of the present disclosure is a semiconductor device that includes a semiconductor chip including a substrate, a plurality of units arranged in an array direction, each of the plurality of units including a unit FET having a gate electrode, a source electrode, and a drain electrode provided on the substrate, and a gate pad to which the gate electrode of each of the plurality of units is electrically connected and that extends in the array direction and is provided on the substrate; an input terminal to which a high-frequency signal is input; and a matching circuit including a plurality of bonding wires electrically connected between the input terminal and the gate pad, each of the plurality of bonding wires having a first end bonded to a respective one of a plurality of regions arranged in the array direction in the gate pad. The plurality of units include a first unit and a second unit, and the first unit is closer to a center of the plurality of units in the array direction than the second unit. The first unit includes a first capacitive element electrically connected between the gate pad and a reference potential. The second unit includes no capacitive element electrically connected between the gate pad and the reference potential, or includes a second capacitive element electrically connected between the gate pad and the reference potential and having a capacitance value smaller than a capacitance value of the first capacitive element. This reduces the variation in characteristics among the units, thereby improving the characteristics.
(2) In the above (1), the first unit may be a unit closest to the center among the plurality of units, and the second unit may be a unit farthest from the center among the plurality of units. This reduces the variation in characteristics among the units, thereby improving the characteristics.
(3) In the above (2), the first capacitive element may have a largest capacitance value among capacitive elements electrically connected between the gate pad and the reference potential in the plurality of units. This makes it possible to increase an amplitude of an impedance of the first unit having the smallest amplitude of the impedance.
(4) In the above (2) or (3), the second unit may include no capacitive element electrically connected between the gate pad and the reference potential. This can reduce the degradation of high-frequency characteristics due to the increase in the gate-source capacitance.
(5) In any one of the above (1) to (4), the plurality of units may include a third unit located between the first unit and the second unit. The third unit may include a third capacitive element electrically connected between the gate pad and the reference potential and having a capacitance value smaller than the capacitance value of the first capacitive element. The third capacitive element may have a capacitance value larger than the capacitance value of the second capacitive element when the second unit includes the second capacitive element. This reduces the variation in characteristics among the units, thereby improving the characteristics.
(6) In any one of the above (1) to (5), the first capacitive element may have an electrode electrically connected to the gate pad and provided on the source electrode with an insulating layer interposed between the source electrode and the electrode. This enables downsizing.
(7) In any one of the above (1) to (6), the semiconductor device may further include a base on which the semiconductor chip is mounted. The matching circuit may be mounted on the base, and may include a dielectric substrate, an electrode provided on the dielectric substrate and extending in the array direction, and a component mounted on the base. A second end of each of the plurality of bonding wires may be bonded to a respective one of a plurality of regions arranged in the array direction in the electrode. This can improve the characteristics.
(8) In any one of the above (1) to (7), the semiconductor chip may amplify the high-frequency signal input to the gate pad. This can improve the characteristics.
(9) In the above (8), the semiconductor device may further include an output terminal that outputs the high-frequency signal amplified by the semiconductor chip. The source electrode may be electrically connected to the reference potential, and the drain electrode may be electrically connected to the output terminal. This can improve the characteristics.
(10) In any one of the above (1) to (9), an angle of impedance as viewed from the gate electrode to the matching circuit at a frequency twice a center frequency of an operating band may be within a range of −150 degrees to −15 degrees, inclusive, when a Smith chart is expressed in polar coordinates in which an angle at an open-circuit position is set to zero degrees and an angle increases counterclockwise. Accordingly, the amplitude of the impedance can be increased by shunt-connecting the first capacitive element.
(11) In the above (10), a first impedance as viewed from the gate electrode of the first unit to the matching circuit when the first capacitive element is not provided may have a smaller radius vector magnitude in the polar coordinates than a second impedance as viewed from the gate electrode of the second unit to the matching circuit when the second capacitive element is not provided. This can improve the characteristics.
(12) An embodiment of the present disclosure is a semiconductor device including a substrate; a plurality of units arranged in an array direction on the substrate, each of the plurality of units including a unit FET having a gate electrode, a source electrode, and a drain electrode; and a gate pad to which the gate electrode of each of the plurality of units is connected and that extends in the array direction and is provided on the substrate. The plurality of units include a first unit and a second unit, and the first unit is closer to a center of the plurality of units in the array direction than the second unit. The first unit includes a first capacitive element electrically connected between the gate pad and a reference potential. The second unit includes no capacitive element electrically connected between the gate pad and the reference potential, or includes a second capacitive element electrically connected between the gate pad and the reference potential and having a capacitance value smaller than a capacitance value of the first capacitive element. This reduces the variation in characteristics among the units, thereby improving the characteristics.

### Details of Embodiments of the Present Disclosure

Specific examples of a semiconductor device according to embodiments of the present disclosure will be described below with reference to the drawings. The present disclosure is not limited to these examples, but is defined by the claims, and is intended to include all modifications within the scope and meaning equivalent to the appended claims.

### First Embodiment

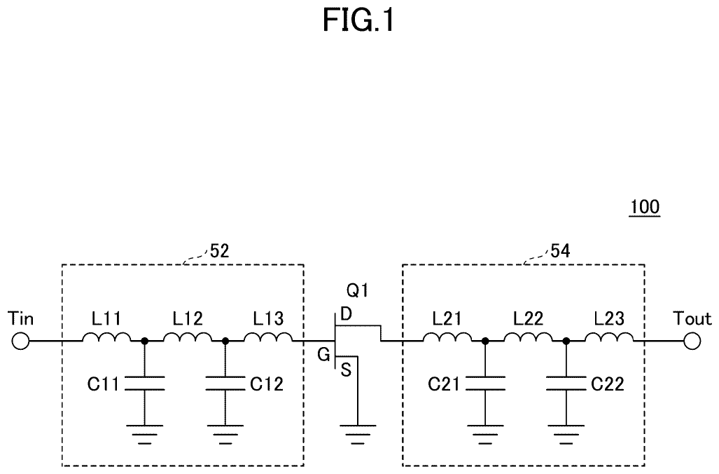

An amplifier circuit will be described as an example of a high-frequency circuit. FIG. 1 is a circuit diagram of a semiconductor device according to a first embodiment. As illustrated in FIG. 1, a semiconductor device 100 includes a transistor Q1, matching circuits 52 and 54, an input terminal Tin, and an output terminal Tout.

A high-frequency signal is input to the input terminal Tin. A frequency of the high-frequency signal is, for example, from 0.5 GHz to 20 GHz, inclusive. The matching circuit 52 matches an impedance as viewed from the gate G of the transistor Q1 to the matching circuit 52 with an impedance as viewed from the matching circuit 52 to the input terminal Tin. The matching circuit 52 includes inductors L11 to L13 and capacitors C11 and C12. The inductors L11 to L13 are connected in series between the input terminal Tin and the gate G. The capacitor C11 is shunt-connected to a node between inductors L11 and L12. The capacitor C12 is shunt-connected to a node between the inductors L12 and L13.

The transistor Q1 is a field effect transistor (FET) and has a source S, a gate G, and a drain D. The source S is electrically connected to a reference potential such as ground. The gate G is electrically connected to the input terminal Tin via the matching circuit 52. The drain D is electrically connected to the output terminal Tout via the matching circuit 54. The transistor Q1 amplifies the high-frequency signal input to the gate G and outputs the amplified high-frequency signal from the drain D. The transistor Q1 is, for example, a gallium nitride high electron mobility transistor (GaN HEMT) or a laterally diffused metal oxide semiconductor (LDMOS).

The matching circuit 54 matches an impedance as viewed from the output terminal Tout to the matching circuit 54 with an impedance as viewed from the matching circuit 54 to the drain D of the transistor Q1. The matching circuit 54 includes inductors L21 to L23 and capacitors C21 and C22. The inductors L21 to L23 are connected in series between the drain D and the output terminal Tout. The capacitor C21 is shunt-connected to a node between inductors L21 and L22. The capacitor C22 is shunt-connected to a node between the inductors L22 and L23. The output terminal Tout outputs the high-frequency signal amplified by the transistor Q1. The circuit configurations of the matching circuits 52 and 54 are examples, and the circuit configurations of the matching circuits 52 and 54 can be set as appropriate.

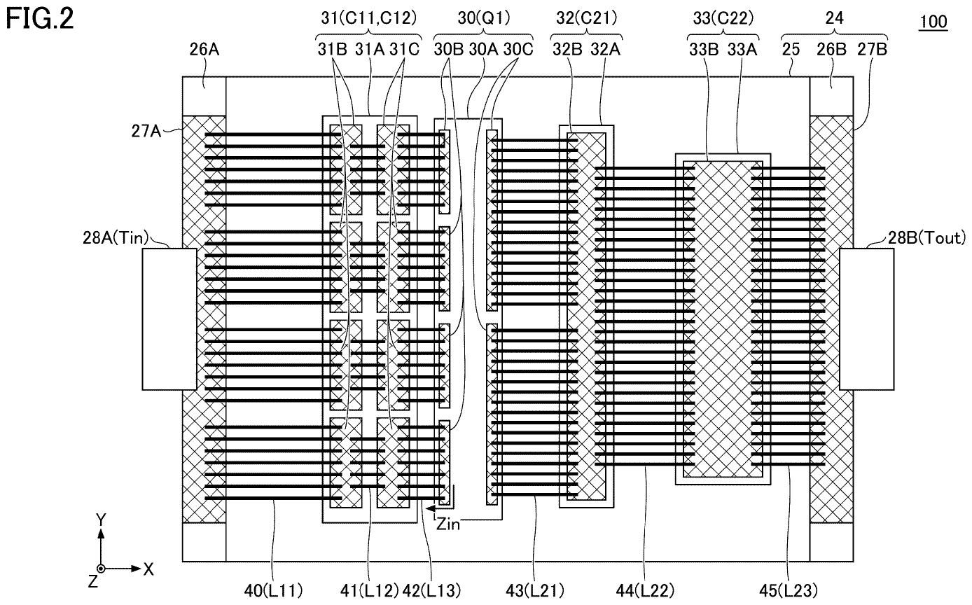

FIG. 2 is a plan view of the semiconductor device according to the first embodiment. A thickness direction of a base 25 is defined as a Z-axis direction, a direction from a lead 28A toward a lead 28B is defined as an X-axis direction, and a direction orthogonal to the X-axis direction is defined as a Y-axis direction.

As illustrated in FIG. 2, the semiconductor device 100 includes a package 24, a semiconductor chip 30, and capacitive components 31, 32, and 33. The package 24 includes the base 25, dielectric layers 26A and 26B, pads 27A and 27B, and the leads 28A and 28B. The package 24 may include a lid that covers the base 25.

At least the upper surface of the base 25 is a conductor, and the base 25 is a metal plate in which a copper plate, a molybdenum plate, and a copper plate are layered. A reference potential such as a ground potential is supplied to the base 25. The dielectric layers 26A and 26B are mounted on one end and the other end of the base 25 in the X-axis direction, respectively. The dielectric layers 26A and 26B may be frames surrounding the semiconductor chip 30 and the capacitive components 31 to 33. The dielectric layers 26A and 26B are made of ceramic or resin. The pads 27A and 27B are provided on the dielectric layers 26A and 26B, respectively. The pads 27A and 27B are metal layers such as copper layers. The leads 28A and 28B are provided on the pads 27A and 27B in electrical contact therewith, respectively. The leads 28A and 28B may be feedthroughs. The leads 28A and 28B are metal leads such as copper leads.

The capacitive component 31, the semiconductor chip 30, and the capacitive components 32 and 33 are mounted on the base 25 and are arranged in order in the X-axis direction. The semiconductor chip 30 includes a substrate 30A, pads 30B and 30C provided on the substrate 30A, and an electrode provided under the substrate 30A. The pads 30B and 30C and the electrode under the substrate 30A are electrically connected to the gate G, the drain D, and the source S of the transistor Q1, respectively, and are short-circuited. When the transistor Q1 is a GaN HEMT, the substrate 30A is, for example, a silicon carbide substrate or a sapphire substrate. When the transistor Q1 is an LDMOS, the substrate 30A is, for example, a silicon substrate. The pads 30B and 30C are metal layers, such as gold layers or copper layers.

The capacitive component 31 includes a dielectric substrate 31A, pads 31B and 31C, and an electrode under the dielectric substrate 31A. The capacitive components 32 and 33 have dielectric substrates 32A and 33A, respectively, pads 32B and 33B, respectively, and electrodes under the dielectric substrates. The dielectric substrates 31A, 32A, and 33A are, for example, alumina substrates or barium titanate substrates. The pads 31B, 31C, 32B, and 33B are metal layers, such as gold layers or copper layers. The dielectric substrate 31A, and the pad 31B and the electrode under the dielectric substrate 31A, which sandwich the dielectric substrate 31A, correspond to the capacitor C11. The dielectric substrate 31A, and the pad 31C and the electrode under the dielectric substrate 31A, which sandwich the dielectric substrate 31A, correspond to the capacitor C12. The dielectric substrate 32A, and the pad 32B and the electrode under the dielectric substrate 32A, which sandwich the dielectric substrate 32A, correspond to the capacitor C21. The dielectric substrate 33A, and the pad 33B and the electrode under the dielectric substrate 33A, which sandwich the dielectric substrate 33A, correspond to the capacitor C22.

Bonding wires 40 electrically connect the pad 27A to the pad 31B, bonding wires 41 electrically connect the pad 31B to the pad 31C, and bonding wires 42 electrically connect the pad 31C to the pad 30B. Bonding wires 43 electrically connect the pad 30C to the pad 32B, bonding wires 44 electrically connect the pad 32B to the pad 33B, and bonding wires 45 electrically connect the pad 33B to the pad 27B. The bonding wires 40 to 45 are thin metal wires, such as gold wires or aluminum wires. The bonding wires 40, 41, 42, 43, 44, and 45 correspond to inductors L11, L12, L13, L21, L22, and L23, respectively.

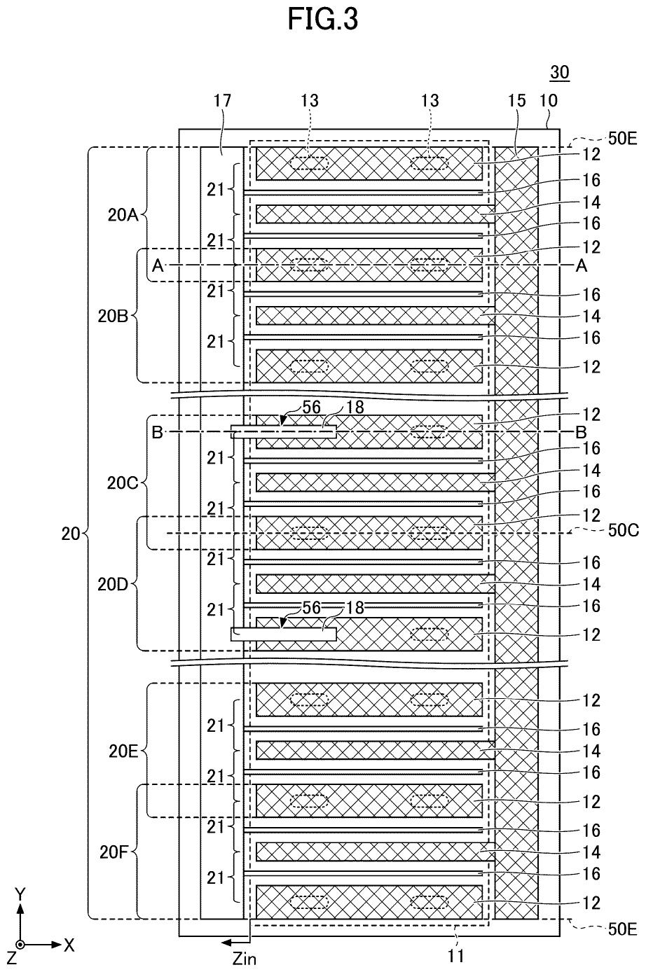

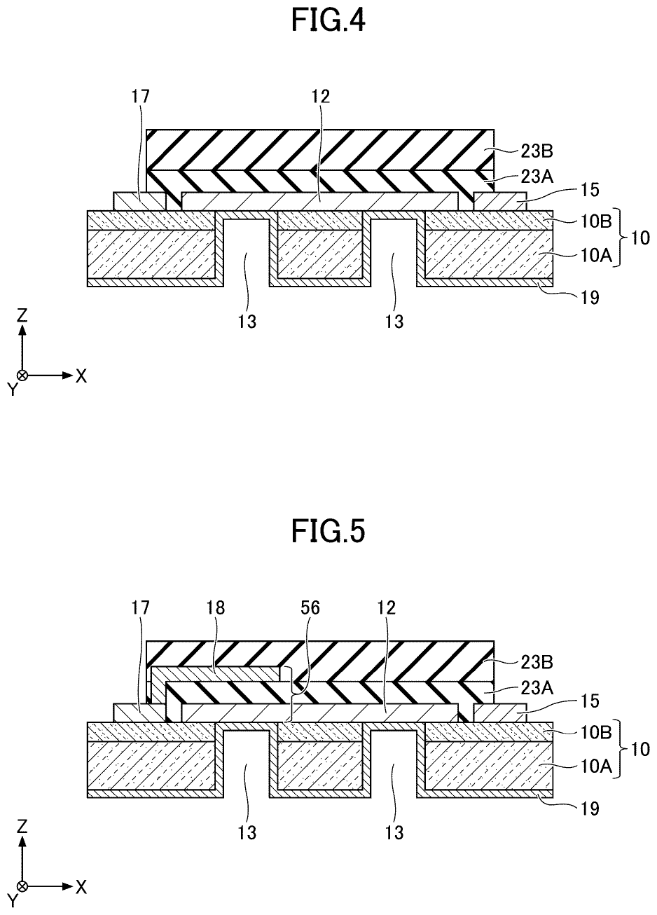

The semiconductor chip 30 will be described using a GaN HEMT as an example. FIG. 3 is a plan view of a semiconductor chip in the first embodiment. FIG. 4 is a cross-sectional view taken along line A-A in FIG. 3. FIG. 5 is a cross-sectional view taken along line B-B in FIG. 3. As illustrated in FIG. 3 to FIG. 5, the semiconductor chip 30 includes a substrate 10 and a plurality of units 20A to 20F. The substrate 10 includes a substrate 10A and a semiconductor layer 10B provided on the substrate 10A. An active region 11 is provided in the substrate 10. In an inactive region other than the active region 11, the semiconductor layer 10B is inactivated. The substrate 10A is, for example, a silicon carbide substrate or a sapphire substrate. The semiconductor layer 10B includes, for example, a gallium nitride electron transit layer and an aluminum gallium nitride electron supply layer provided on the electron transit layer.

A plurality of units 20 are provided on the substrate 10 and arranged in the Y-axis direction (array direction). The plurality of units 20 include units 20A to 20F. Each of the units 20A to 20F includes two unit FETs 21, a gate pad 17, and a drain pad 15. The unit FET 21 includes a source electrode 12, a drain electrode 14, and a gate electrode 16. The source electrode 12, the drain electrode 14, and the gate electrode 16 are provided on the active region 11. The source electrode 12, the drain electrode 14, and the gate electrode 16 are finger-shaped electrodes extending in the X-axis direction. The gate electrode 16 is provided between the source electrode 12 and the drain electrode 14 arranged in the Y-axis direction. The neighboring unit FETs 21 share the source electrode 12 or the drain electrode 14. The source electrode 12 and the drain electrode 14 are, for example, metal layers including a titanium film provided on the substrate 10 and an aluminum film or the like provided on the titanium film. The gate electrode 16 is, for example, a metal layer including a nickel film provided on the substrate 10 and a gold film or the like provided on the nickel film.

Each of the units 20A to 20F has the same number of the unit FETs 21. The number of the unit FETs 21 included in each of the units 20A to 20F may be one or three or more. The units 20A to 20F are partitioned so as to have the same planar shape and the same characteristics within the extent of manufacturing error. In the example in FIG. 3, the neighboring unit FETs 21 are mirror symmetric but not parallel symmetric. The unit FETs 21 are in parallel symmetry every two unit FETs 21. In such a case, the number of the unit FETs 21 included in each of the units 20A to 20F may be two or a multiple of two. In order to increase the output of the transistor Q1, the number of the unit FETs 21 and the number of the units 20A to 20F, which are connected in parallel, are increased. The number of the unit FETs 21 is, for example, 20 or more, or 40 or more, and is 64 as an example. The number of the units 20A to 20F is, for example, 10 or more, or 20 or more, and is 32 as an example.

The center of the plurality of units 20 (for example, 32 units) in the Y-axis direction is denoted as 50C, and each edge of the plurality of units 20A to 20F in the Y-axis direction is denoted as 50E. The units 20C and 20D are units closest to the center 50C among the plurality of units 20A to 20F. The units 20A and 20F are units closest to the edges 50E among the plurality of units 20A to 20F.

The drain pad 15 corresponds to the pad 30C in FIG. 2, is provided at an end of the substrate 10 in a positive direction along the X-axis, and extends in the Y-axis direction. The drain pad 15 may be one, but may be divided into a plurality of parts in the Y-axis direction as in the pad 30B in FIG. 2. Each of the drain electrodes 14 is electrically connected to the drain pad 15 in common and is short-circuited. The gate pad 17 is provided at an end of the substrate 10 in a negative direction along the X-axis and extends in the Y-axis direction. The gate pad 17 may be one, but may be divided into a plurality of parts in the Y-axis direction as in the pad 30B in FIG. 2. Each of the gate electrodes 16 is electrically connected to the gate pad 17 in common and is short-circuited.

A via 13 is provided so as to penetrate the substrate 10 in the Z-axis direction. A metal layer 19 is provided on a surface of the substrate 10 facing a negative direction along the Z-axis and a side surface of the via 13. The metal layer 19 is electrically connected to the source electrode 12 through the via 13. As a result, a reference potential is supplied to the source electrode 12 through the base 25 and the metal layer 19. The metal layer 19 is, for example, a gold layer. An insulating layer 23A is provided on the substrate 10 so as to cover the units 20A to 20F. The insulating layer 23A is not provided on regions of the surfaces of the gate pad 17 and the drain pad 15 to which the bonding wires 42 and 43 are bonded. An insulating layer 23B is provided on the insulating layer 23A. The insulating layers 23A and 23B are, for example, silicon nitride layers.

The units 20C and 20D each include a capacitive element 56. The capacitive element 56 has an electrode 18. The electrode 18 is provided between the insulating layers 23A and 22B, and faces the source electrode 12 with the insulating layer 23A interposed between the electrode 18 and the source electrode 12. The electrode 18 is electrically connected to the gate pad 17 and is short-circuited. Accordingly, the insulating layer 23A, and the source electrode 12 and the electrode 18, which sandwich the insulating layer 23A, function as the capacitive element 56 connected between the gate pad 17 and the reference potential. None of the units 20A, 20B, 20E, and 20F include the capacitive element 56.

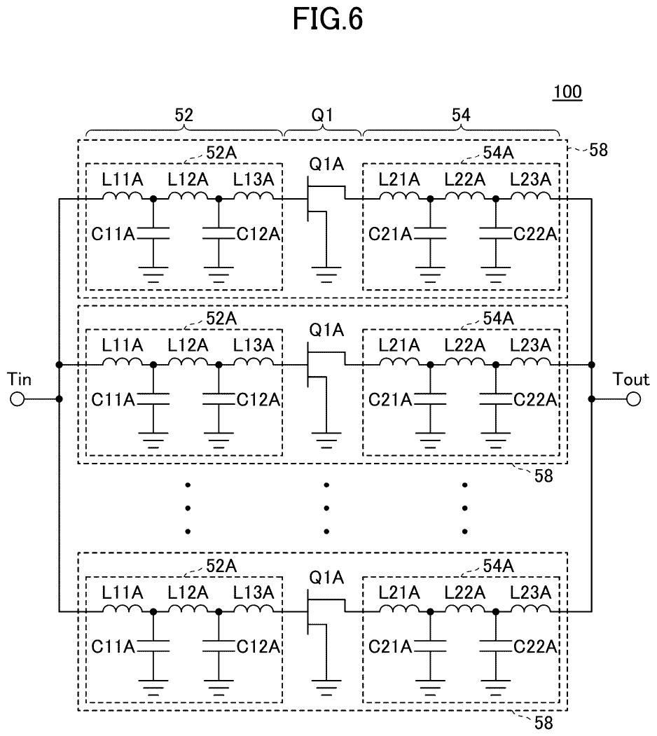

FIG. 6 is an equivalent circuit diagram of a semiconductor device according to the first embodiment. When physical lengths of the semiconductor chip 30 and the capacitive components 31 to 33 in the Y-axis direction increase and the number of each of the bonding wires 40 to 43 increases, the influence of the wavelength of the high-frequency signal in the matching circuits 52 and 54 cannot be ignored, resulting in a distributed constant circuit. Therefore, the circuit of the semiconductor device 100 in FIG. 1 is equivalently represented as a circuit in which a plurality of paths 58 are connected in parallel between the input terminal Tin and the output terminal Tout as illustrated in FIG. 6. Each of the paths 58 includes matching circuits 52A and 54A and a transistor Q1A. Each of the matching circuits 52A includes inductors L11A, L12A, and L13A, and capacitors C11A and C12A. Each of the matching circuits 54A includes inductors L21A, L22A, and L23A, and capacitors C21A and C22A. The transistors Q1A correspond to the units 20A to 20F.

The matching circuit 52A in the path 58 is affected by a neighboring matching circuit 52A. Therefore, a matching circuit 52A near the center and a matching circuit 52A near the end, among the plurality of matching circuits 52A, may have different characteristics such as impedance.

### Simulation

An electromagnetic field analysis between the lead 28A and the pad 30B of the semiconductor device 100 in FIG. 2 was performed, and an impedance Zin as viewed from the gate electrode 16 in FIG. 3 to the gate pad 17 (pad 30B) was simulated. The simulated semiconductor device 100 is an amplifier circuit having a center frequency f0 of an operating band of approximately 3.8 GHz and an output power of 180 W. The number of units 20A to 20F is 32.

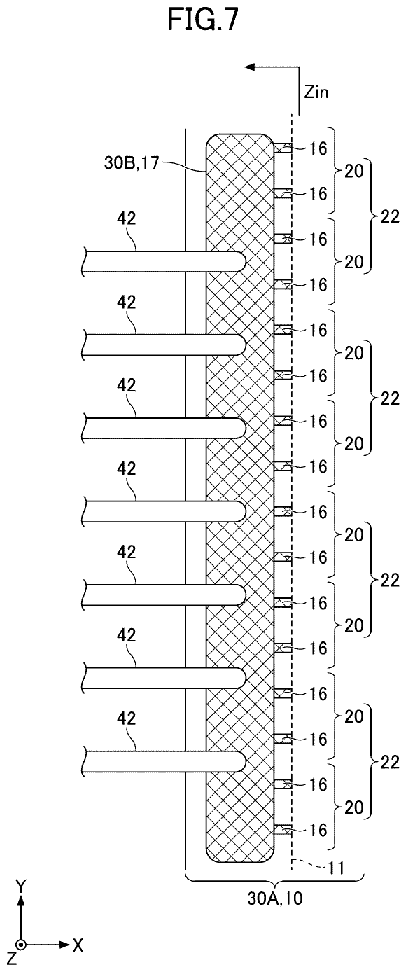

FIG. 7 is a plan view illustrating a part of a semiconductor chip in the simulation. FIG. 7 illustrates one pad 30B of the semiconductor chip 30 in FIG. 2. Seven bonding wires 42 are bonded to the one pad 30B. The first end of each of the bonding wires 42 is bonded to a respective one of a plurality of regions arranged in the Y-axis direction in the pad 30B. The sixteen gate electrodes 16 are connected to one pad 30B. In the simulation model, an edge of each of the gate electrodes 16 is located at an edge of the active region 11, and the gate electrode 16 is not provided on the active region 11. Since each of the units 20 has two unit FETs 21, the one pad 30B corresponds to eight units 20. Here, for the purpose of improving the efficiency of the simulation, the two units 20 are set as a unit 22. Thus, one pad corresponds to four units 22. The semiconductor chip 30 includes 16 units 22 as a whole.

Impedances Zin as a unit average and for each of the units 22 were simulated. For the unit average, the impedance Zin was calculated by treating 16 units 22 as one unit. The impedance Zin calculated by this method corresponds to an average impedance of the impedances Zin for the 16 units 22. The impedance Zin was calculated for each of the 16 units 22. The impedance Zin calculated by this method corresponds to an impedance as viewed from each of the units 22.

### Sample A

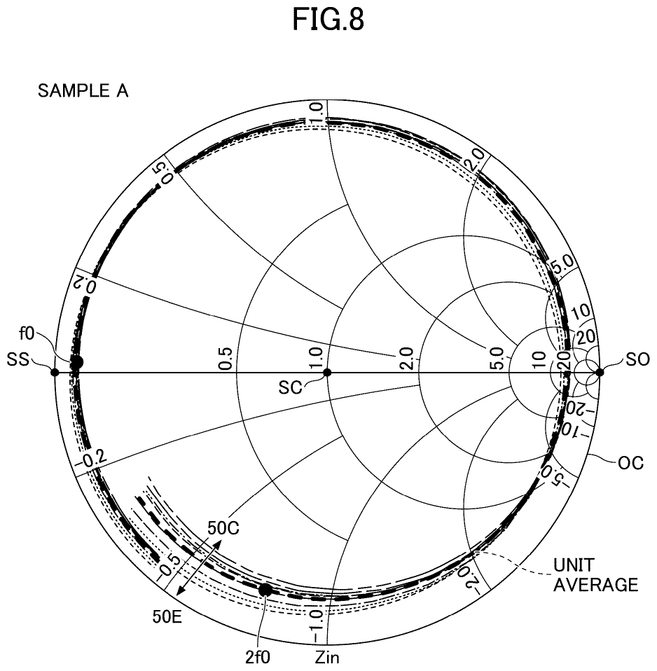

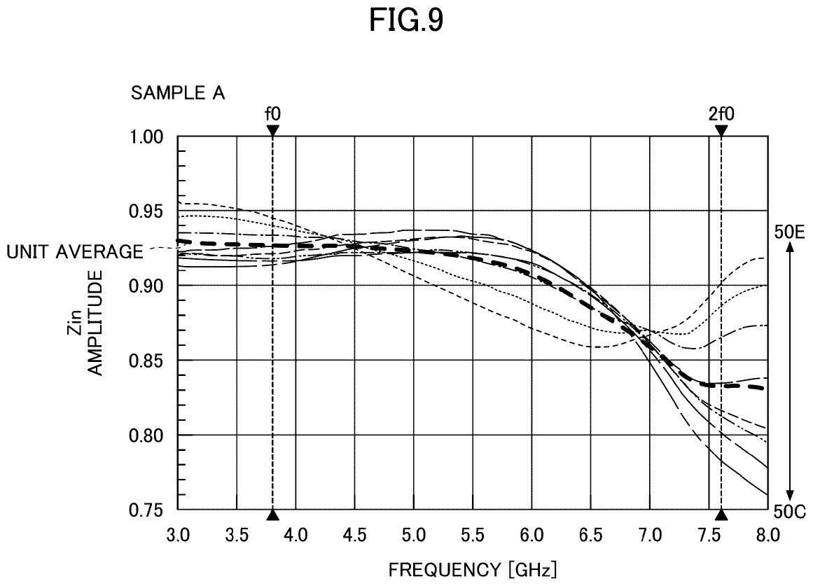

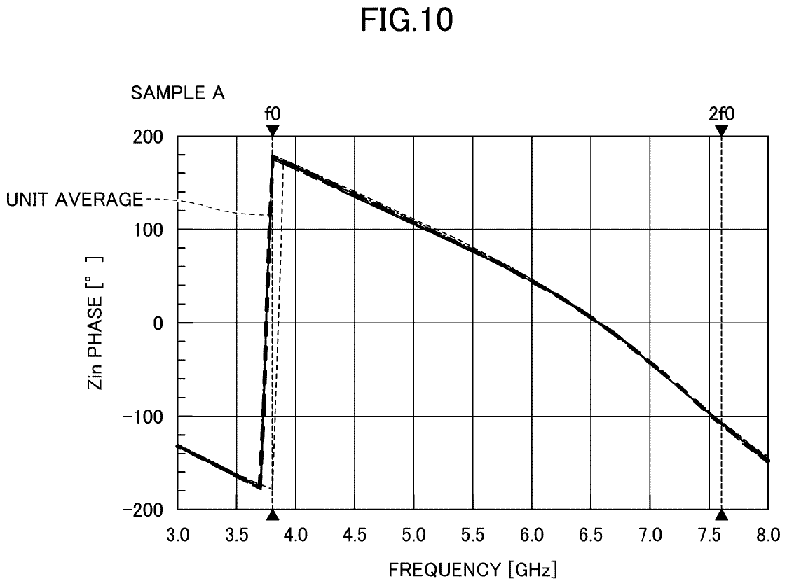

As a sample A, an impedance Zin was calculated for a sample in which the capacitive element 56 was not provided in any of the units 20. FIG. 8 is a Smith chart illustrating an impedance Zin versus a frequency in the sample A. The impedance Zin corresponds to an S parameter S11 when the edge of the gate electrode 16 is a port 1. FIG. 9 is a diagram illustrating an amplitude of the impedance Zin versus the frequency in the sample A. FIG. 10 is a diagram illustrating a phase of the impedance Zin versus the frequency in the sample A. A radius vector magnitude is referred to as an amplitude when the Smith chart in FIG. 8 is expressed in polar coordinates, a center SC of the Smith chart is set to zero, and the outer circumference OC of the Smith chart is set to one. The right end of the Smith chart is an open-circuit position SO. When an angle of the position SO is set to zero degrees with the center SC as the center, a counterclockwise angle is referred to as the phase. At a short-circuit position SS at the left end of the Smith chart, the phases are 180 degrees and −180 degrees.

As illustrated in FIG. 8 to FIG. 10, at the frequency f0 (3.8 GHz), the difference in amplitude between the units is not so large, and is 0.9 or more, and the phase is approximately 180 degrees. Thus, the impedance Zin is located substantially at the short-circuit position SS. When the frequency increases, the phase rotates clockwise and the amplitude decreases. At a frequency 2f0 (7.6 GHz), the amplitude ranges from 0.75 to 0.90, and the phase is approximately −110 degrees. The amplitude at the frequency 2f0 is smaller in a unit 22 (inner unit) close to the center 50C in FIG. 3, and is larger in a unit 22 (outer unit) close to the edge 50E.

In order to pass a signal having a center frequency f0, an impedance Zin at the center frequency f0 is set to be nearly at the short-circuit position SS. At the frequency 2f0 at which the efficiency of the semiconductor device 100 is highest, the position of the impedance Zin in the Smith chart is a position at which the amplitude is close to one and the phase is slightly larger than −180 degrees (that is, the absolute value of the phase is small). When the phase is rotated clockwise from the position of the impedance Zin at which the efficiency is highest, the efficiency decreases sharply. When the phase is rotated counterclockwise from the position of the impedance Zin at which the efficiency is highest, the efficiency gradually decreases. The efficiency is lowest when the phase at the frequency 2f0 is around 180 degrees. As described above, the efficiency sharply decreases at a position where the phase at the frequency 2f0 is slightly larger than −180 degrees. Thus, considering a manufacturing variation in phase at the frequency 2f0, the phase at the frequency 2f0 is within a range of −150 degrees to −15 degrees, inclusive.

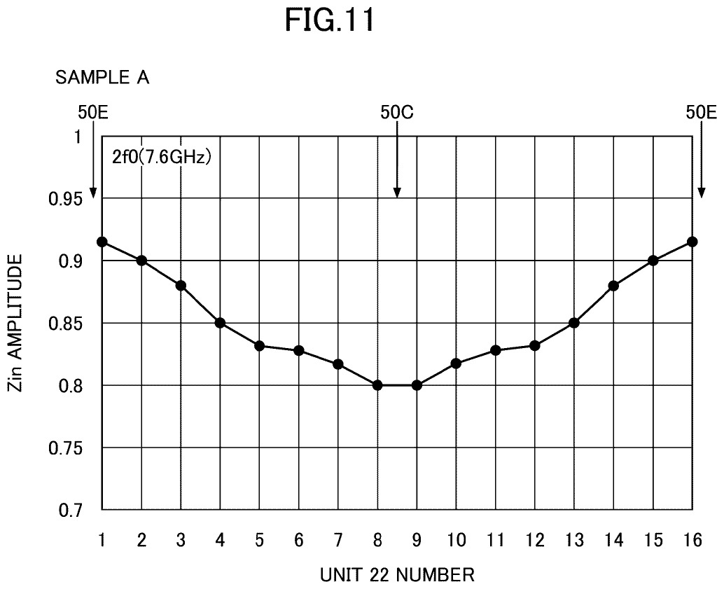

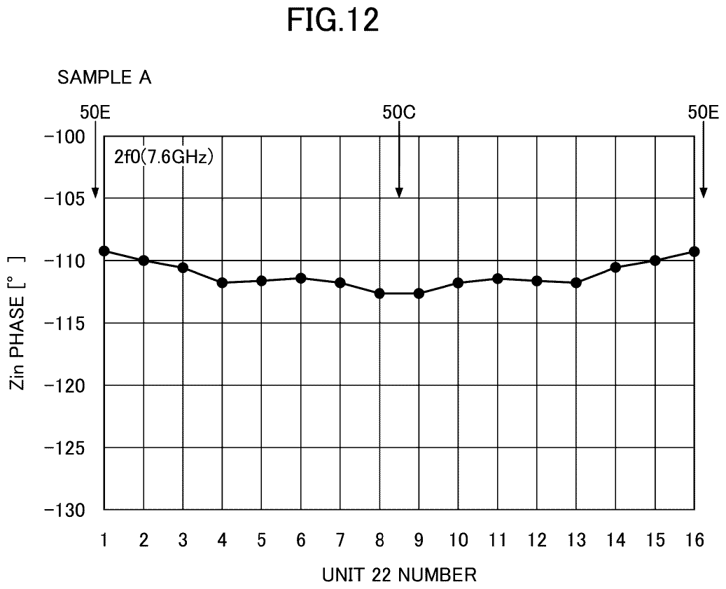

FIG. 11 is a diagram illustrating an amplitude of the impedance Zin versus a unit number at the frequency 2f0 (7.6 GHz) in the sample A. FIG. 12 is a diagram illustrating a phase of the impedance Zin versus the unit number at the frequency 2f0 (7.6 GHz) in the sample A. In FIG. 11 and FIG. 12, horizontal axes represent the unit number of the units 22. The center 50C is located between the unit numbers 8 and 9, and the edges 50E are located outside the unit numbers 1 and 16.

As illustrated in FIG. 11, the Zin amplitude is smallest at the unit numbers 8 and 9, and largest at the unit numbers 1 and 16. The maximum difference in amplitude is 0.12. The amplitude decreases from the edges 50E toward the center 50C. When the amplitude varies greatly, the impedance Zin differs among the units 20. For example, in units close to the edges 50E, the efficiency is higher because the amplitude at the frequency 2f0 is large, but in units close to the center 50C, the efficiency is lower because the amplitude at the frequency 2f0 is small. As a result, the overall characteristics of the units 20 are degraded.

As illustrated in FIG. 12, the Zin phase is smallest at the unit numbers 8 and 9, and largest at the unit numbers 1 and 16. The maximum difference in phase is 3 degrees. The phase decreases from the edges 50E toward the center 50C. Since the difference in phase at the frequency 2f0 among the units 20 is small, it is considered that the degradation of the characteristics due to the variation in phase is small.

The reason why the amplitude of the impedance Zin at the frequency 2f0 of a second harmonic differs among the units 20 is as follows. In the matching circuit 52A corresponding to the units 20C and 20D near the center 50C in the Y-axis direction, a mutual inductance between the bonding wires 40, a mutual inductance between the bonding wires 41, and a mutual inductance between the bonding wires 42, which are arranged in the Y-axis direction, are larger than those in the units 20A and 20E near the edges 50E. Accordingly, inductances of the inductors L11A to L13A of the units 20C and 20D are larger than inductances of the inductors L11A to L13A of the units 20A and 20E. Furthermore, when considering the pads 31B and 31C are regarded as a distributed constants, the high-frequency characteristics of the pads 31B and 31C corresponding to the units 20C and 20D are different from the high-frequency characteristics of the pads 31B and 31C corresponding to the units 20A and 20E, respectively. Accordingly, it is considered that the Zin amplitudes in the units 20C and 20D near the center 50C are smaller than the Zin amplitudes in the units 20A and 20E near the edges 50E.

As illustrated in FIG. 8, when the impedance Zin is capacitive and is located at a lower part of the Smith chart, the impedance is shifted downward by shunt-connecting the capacitor. For example, when the capacitor is shunt-connected to one of the units 20 whose impedance Zin is positioned at a point indicated by 2f0 in the Smith chart of FIG. 8, the impedance Zin at the frequency 2f0 shifts to the lower left, and the amplitude of the impedance Zin increases.

### Sample B

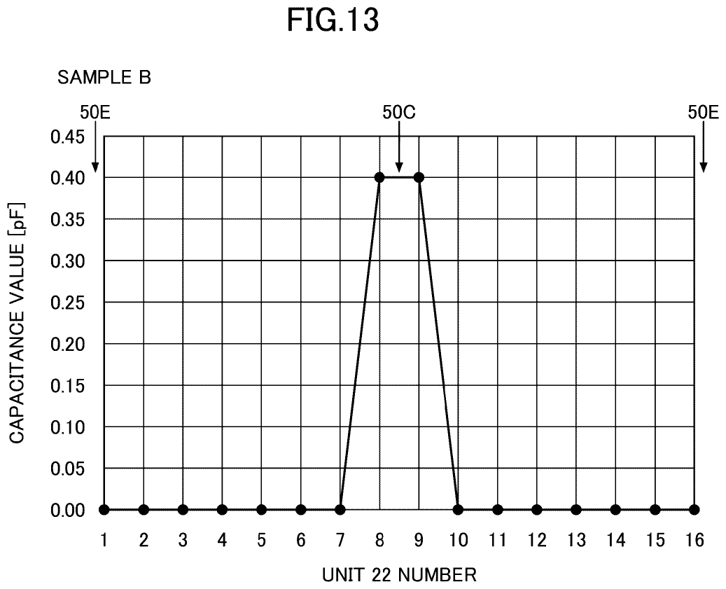

FIG. 13 is a diagram illustrating a capacitance value added to each unit in a sample B. In the sample B, a capacitor having a capacitance of 0.40 pF was shunt-connected to each of the units 22 (unit numbers 8 and 9) closest to the center 50C among 16 units 22. That is, a capacitor having a capacitance of 0.20 pF was shunt-connected to each of the units 20C and 20D. No capacitors are provided in the other units 22.

In FIG. 3 and FIG. 5, when viewed from the Z-axis direction, a length, in the X-axis direction, of a portion of the electrode 18 that overlaps with the source electrode 12 is set to 0.24 mm, a width of the electrode 18 in the Y-axis direction is set to 0.1 mm, and a thickness of the insulating layer 23A in the Z-axis direction between the source electrode 12 and the electrode 18 is set to 800 nm. When the insulating layer 23A is a silicon nitride layer having a dielectric constant of 7.5, a capacitance of the capacitive element 56 in each of the units 20 is 0.20 pF, and the capacitance of each of the units 22 having the two units 20C and 20D is 0.40 pF.

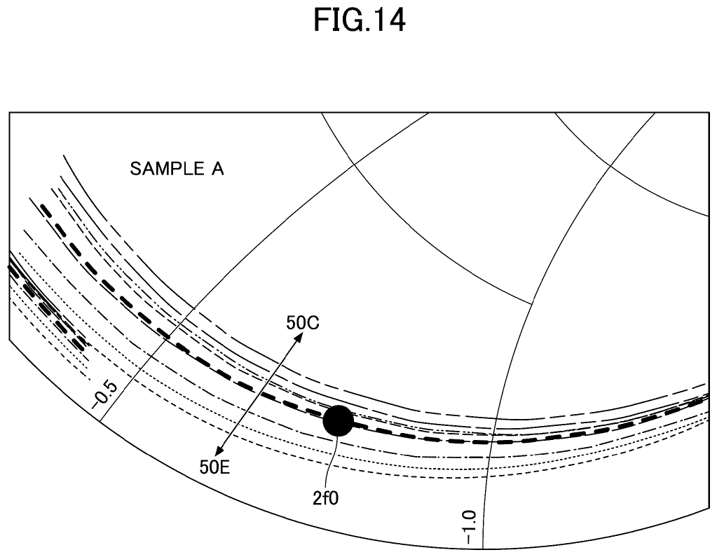

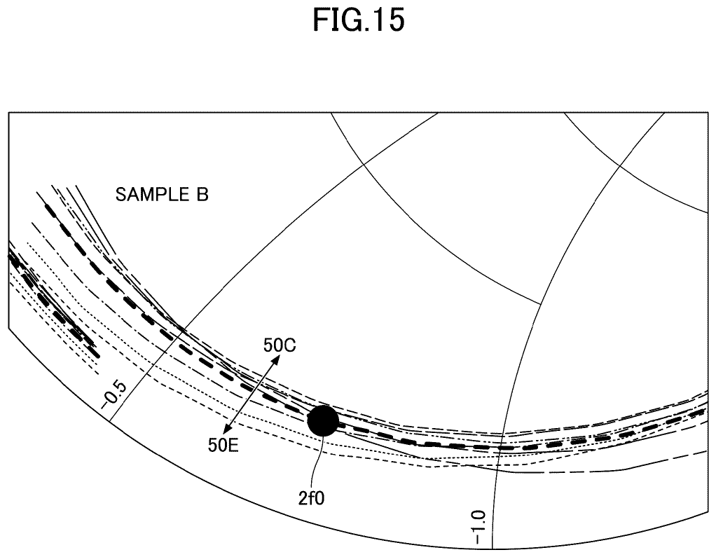

FIG. 14 is an enlarged view of the Smith chart illustrating an impedance Zin versus a frequency in the sample A. FIG. 15 is an enlarged view of a Smith chart illustrating an impedance Zin versus a frequency in the sample B. FIG. 14 and FIG. 15 are enlarged views of a vicinity of the impedance Zin at the frequency of 2f0. When FIG. 14 and FIG. 15 are compared, in the sample B, the variation in Zin amplitude around the frequency 2f0 among the units 22 is smaller than that in the sample A. In particular, the Zin amplitude of a unit 22 close to the center 50C is larger.

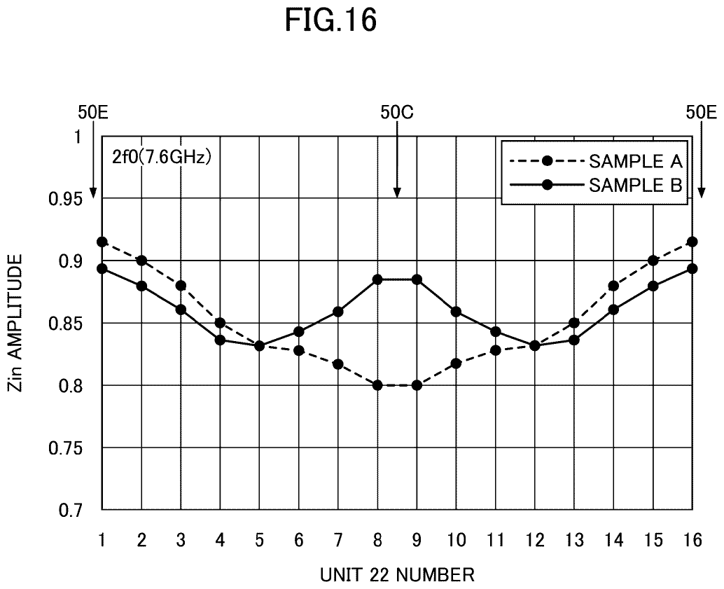

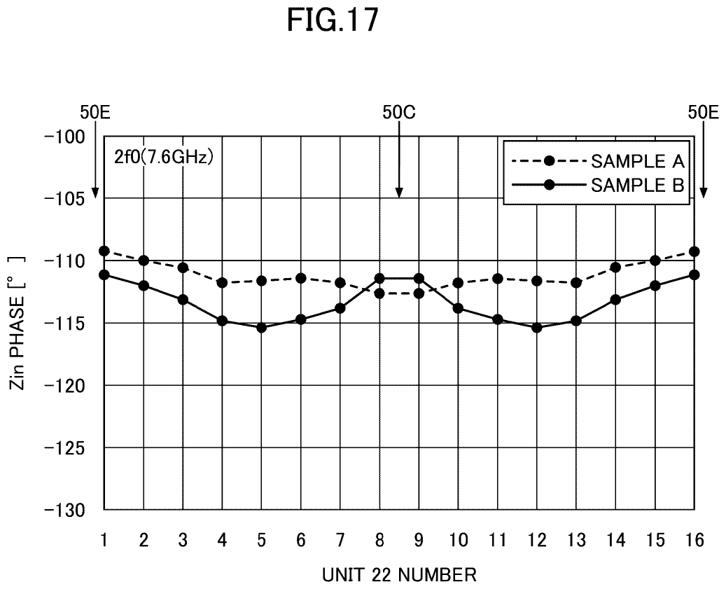

FIG. 16 is a diagram illustrating an amplitude of the impedance Zin versus the unit number in the samples A and B. FIG. 17 is a diagram illustrating a phase of the impedance Zin versus the unit number in the samples A and B. As illustrated in FIG. 16, in the sample B, the amplitudes of the impedances Zin in the units 22 with the numbers 8 and 9 are larger than those in the sample A. The Zin amplitudes with the unit numbers 8 and 9 and the Zin amplitudes with the unit numbers 1 and 16 are substantially the same. Thus, the maximum difference in amplitude in the sample B is 0.06, which is approximately half that of 0.12 in the sample A.

As illustrated in FIG. 17, in the sample B, the phases of the impedances Zin in the units 22 with the numbers 8 and 9 are larger than those in the sample A, and the phases of the impedances Zin in the units 22 with the numbers 1 and 16 are smaller than those in the sample A. The maximum difference in phase in the sample B is 4 degrees, which is nearly equal to that of 3 degrees in the sample A.

As described above, in the sample B, the variation in amplitude of the impedance Zin at the frequency 2f0 among the units 22 can be reduced. Therefore, the high-frequency characteristics of the semiconductor device can be improved.

### Sample C

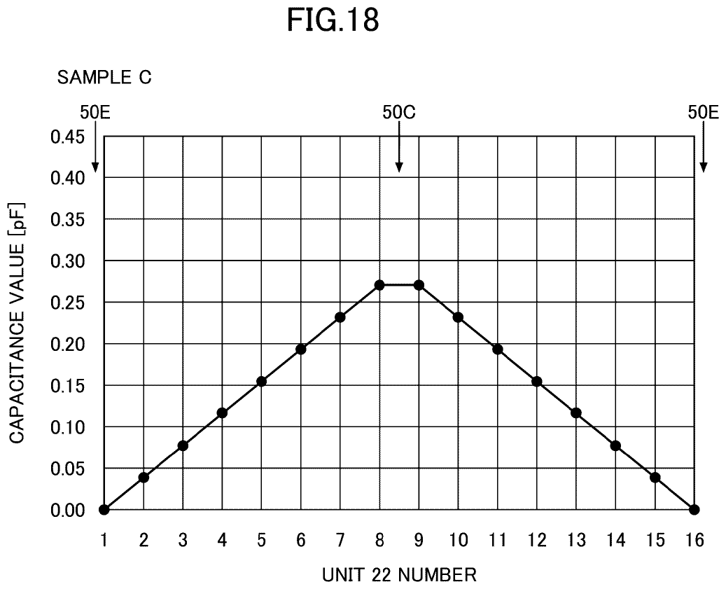

FIG. 18 is a diagram illustrating a capacitance value added to each unit in a sample C. In the sample C, a capacitor having a capacitance of 0.27 pF was shunt-connected to each of the units 22 (unit numbers 8 and 9) closest to the center 50C among 16 units 22. No capacitors are connected to the units 22 (unit numbers 1 and 16) closest to the edges 50E. In the units 22 with the unit numbers 2 to 7 (and 15 to 10), a capacitance of a shunt-connected capacitor increases linearly from the edges 50E toward the center 50C.

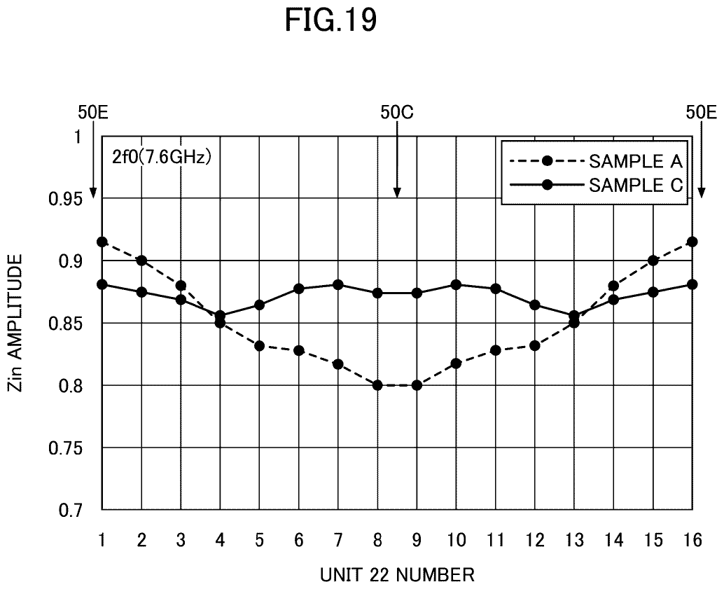

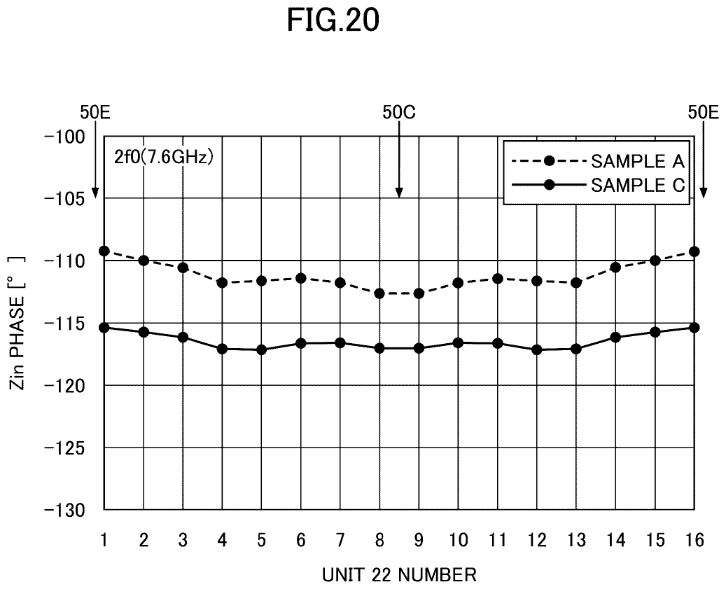

FIG. 19 is a diagram illustrating an amplitude of the impedance Zin versus the unit number in the samples A and C. FIG. 20 is a diagram illustrating a phase of the impedance Zin versus the unit number in the samples A and C. As illustrated in FIG. 19, in the sample C, the Zin amplitudes at the unit numbers 8 and 9 are substantially the same as the Zin amplitudes at the unit numbers 1 and 16, and the Zin amplitudes at the unit numbers 3 to 5 and 12 to 14 approach the Zin amplitudes at the unit numbers 8, 9, 1, and 16. Accordingly, the maximum difference in amplitude in the sample C is 0.03, which is approximately half that of 0.06 in the sample B.

As illustrated in FIG. 20, in the sample C, the Zin phases at the unit numbers 3 to 5 and 12 to 14 approach the Zin phases at the unit numbers 8, 9, 1, and 16. Accordingly, the maximum difference in the Zin phase in the sample C is 2 degrees, which is smaller than those in the samples A and B.

### Sample D

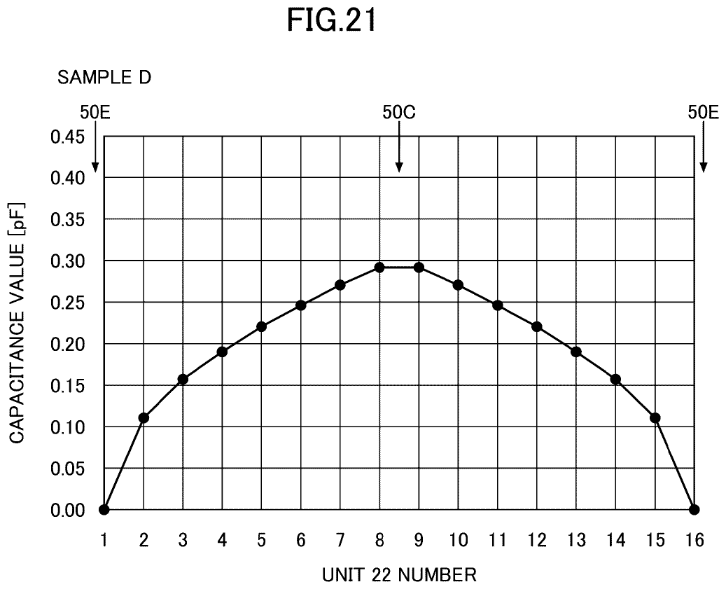

FIG. 21 is a diagram illustrating a capacitance value added to each unit in a sample D. In the units 22 with the unit numbers 2 to 7 (and 15 to 10), a capacitance of a shunt-connected capacitor increases in a curved manner from the edges 50E toward the center 50C. The relational expression of a capacitance value Cn with respect to a unit number n is given by Cn=0.11×(n−1)^{1/2} [pF] for the unit numbers 1 to 8. The unit numbers 9 to 16 are symmetrical to the capacitance values at the unit numbers 1 to 8 with respect to the position of the unit number 8.5.

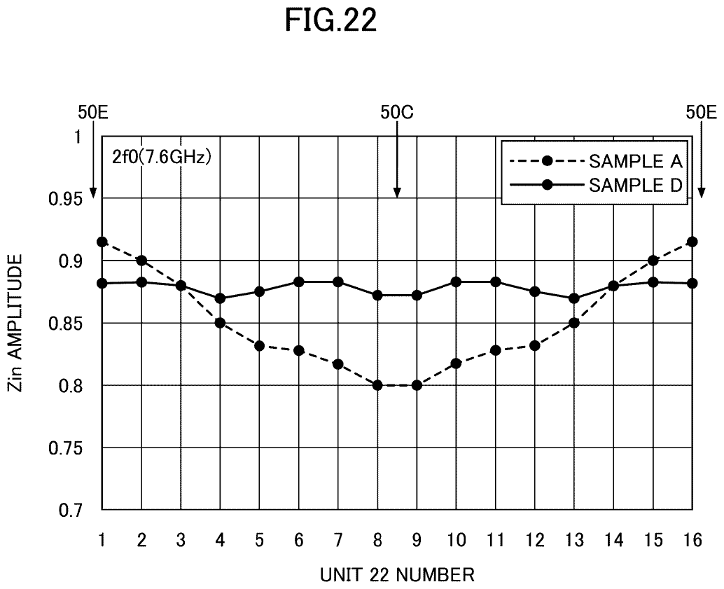

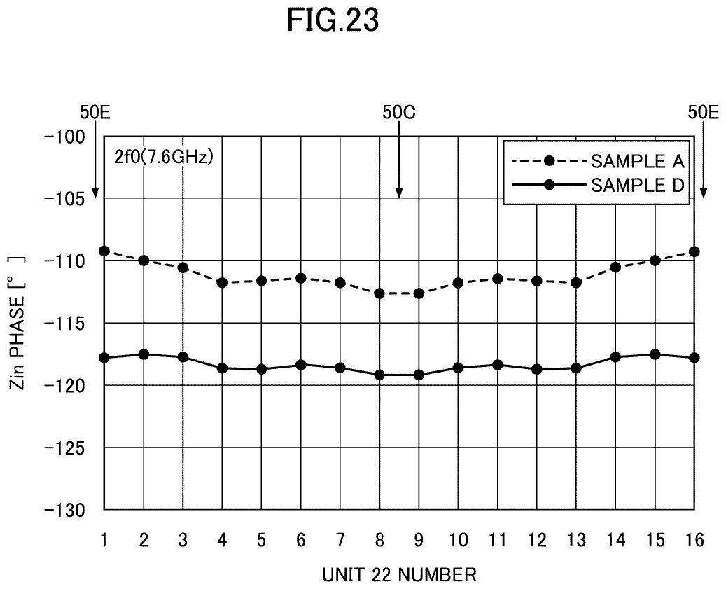

FIG. 22 is a diagram illustrating an amplitude of the impedance Zin versus the unit number in the samples A and D. FIG. 23 is a diagram illustrating a phase of the impedance Zin versus the unit number in the samples A and D. As illustrated in FIG. 22, the maximum difference in amplitude in the sample D is 0.02, which is even smaller than that of 0.03 in the sample C.

As illustrated in FIG. 23, in the sample D, the maximum difference in the Zin phase in the sample D is 2 degrees, which is smaller than those of the samples A and B and is substantially the same as that of the sample C.

As described above, as illustrated in FIG. 2 and FIG. 3, the plurality of units 20A to 20F each have the unit FET 21 and are arranged in the Y-axis direction. As illustrated in FIG. 1 and FIG. 2, the matching circuit 52 includes the plurality of bonding wires 42. The plurality of bonding wires 42 are electrically connected between the input terminal Tin and the gate pad 17, and the first end of each of the bonding wires 42 is bonded to a respective one of the plurality of regions arranged in the Y-axis direction in the gate pad 17. In such a configuration, as in the sample A in FIG. 11, the amplitude of the impedance Zin is different between units 22 close to the center 50C and units 22 close to the edges 50E. Therefore, the high-frequency characteristics such as efficiency are different among the units 20, and the overall characteristics are degraded.

According to the first embodiment, as in the sample B in FIG. 13, the sample C in FIG. 18, and the sample D in FIG. 21, the first unit 22 close to the center 50C includes the first capacitive element 56 electrically connected between the gate pad 17 and the reference potential. The second unit 22 closer to the edge 50E than the first unit 22 does not include the capacitive element 56 electrically connected between the gate pad 17 and the reference potential. Alternatively, the second unit 22 includes a second capacitive element electrically connected between the gate pad 17 and the reference potential and having a capacitance value smaller than that of the first capacitive element. This can reduce the variation in amplitude of the impedance Zin at the frequency 2f0 as illustrated in FIG. 16, FIG. 19, and FIG. 22. Thus, the variation in high-frequency characteristics such as efficiency among the units 20 is reduced, and the overall characteristics can be improved.

As illustrated in FIG. 13, FIG. 18, and FIG. 21, the first unit may include the units with the unit numbers 8 and 9, which are closest to the center 50C among the plurality of units 22. This makes it possible to increase the amplitude of the impedance Zin of the first unit having the smallest amplitude of the impedance Zin as illustrated in FIG. 15. In addition, the second unit may be the units with the unit numbers 1 and 16 which are farthest from the center 50C among the plurality of units 22. Accordingly, the amplitude of the impedance Zin of the second unit having the largest amplitude of the impedance Zin can be held. Thus, the variation in high-frequency characteristics such as efficiency among the units 20 is reduced, and the overall characteristics can be improved.

The first capacitive elements 56 of the units with the unit numbers 8 and 9, which are closest to the center 50C, may have the largest capacitance value among the capacitive elements electrically connected between the gate pad and the reference potential in the plurality of units. This makes it possible to increase the amplitude of the impedance Zin of the first unit having the smallest amplitude of the impedance Zin. When the units with the unit numbers 1 and 16, which are farthest from the center 50C, have capacitive elements electrically connected between the gate pad and the reference potential, the capacitive elements of the units with the unit numbers 1 and 16 may have the smallest capacitance value among the capacitive elements electrically connected between the gate pad and the reference potential in the plurality of units.

As in the sample C in FIG. 18 and the sample D in FIG. 21, the third unit is located between the first unit and the second unit, is electrically connected between the gate pad 17 and the reference potential, and includes a third capacitive element having a capacitance value smaller than that of the first capacitive element. When the second unit includes the second capacitive element, the capacitance value of the third capacitive element is larger than the capacitance value of the second capacitive element. This reduces the variation in high-frequency characteristics such as efficiency among the units 20, thereby improving the overall characteristics.

By providing the capacitive element 56, it is possible to reduce the variation in impedance Zin among the units 20. However, when a large number of capacitive elements 56 are provided, a capacitance value other than an intrinsic gate-source capacitance of the transistor Q1 increases. This degrades the high-frequency characteristics such as a gain of the transistor Q1.

The second unit farthest from the center 50C does not include the capacitive element 56 electrically connected between the gate pad 17 and the reference potential. This can reduce the degradation of the high-frequency characteristics of the transistor Q1.

As in the sample B in FIG. 13, each of the units with the unit numbers 1 to 7 and 10 to 16, that is, with the unit numbers other than the unit numbers 8 and 9 closest to the center 50C, does not have to include the capacitive element 56. This can reduce the degradation of the high-frequency characteristics of the transistor Q1 caused by the capacitance value of the capacitive element 56. As in the sample C in FIG. 18 and the sample D in FIG. 21, the capacitance of the capacitive element 56 may gradually increase from the edges 50E toward the center 50C. Although an example in which each of the units 22 with the unit numbers 1 and 16 farthest from the center 50C does not include the capacitive element 56 has been described, each of the units 22 with the unit numbers 1 and 16 may include the capacitive element 56.

A gate-source capacitance Cgs in the units 20 is approximately 1.5 pF per unit 20 under a bias condition in the idle state. A capacitance of the capacitive element 56 of each of the units 20 in the unit 22 closest to the center 50C may be 0.02 to 1.0 times as large as Cgs.

As illustrated in FIG. 3 and FIG. 4, the capacitive element 56 has the electrode 18 electrically connected to the gate pad 17 and provided on the source electrode 12 with the insulating layer 23A interposed between the electrode 18 and the source electrode 12. This makes it possible to form the capacitive element 56 without changing the chip size. Thus, the semiconductor device can be downsized. The capacitive element may be an open stub having a length that is less than one quarter of the wavelength λ corresponding to the frequency 2f0. When the open stub is used, a chip size increases. As the capacitive element, an electrode to which a reference potential is supplied may be provided on the gate pad 17, with the insulating layer 23A interposed between the electrode and the gate pad 17. In this case, an area of a region of the gate pad 17 to which the bonding wire 42 is bonded is reduced.

As illustrated in FIG. 2, the capacitive component 31 (component) is mounted on the base 25, and includes the dielectric substrate 31A and the pad 31C (electrode) provided on the dielectric substrate 31A and extending in the Y-axis direction. The second end of each of the plurality of bonding wires 42 is bonded to a respective one of a plurality of regions arranged in the Y-axis direction in the pad 31C. In this case, the mutual inductance of the bonding wires 42 differs among the units 22. Furthermore, when the pad 31C is regarded as a distributed constant, the high-frequency characteristic of the pad 31C is different among the units 22. As a result, the Zin amplitude differs among the units 22. Thus, by providing the capacitive element 56, the variation in impedance Zin can be reduced, thereby improving the characteristics.

As illustrated in FIG. 1 and FIG. 2, the semiconductor chip 30 amplifies a high-frequency signal input to the gate pad 17. In the amplifier circuit, the efficiency and other characteristics vary in accordance with the input impedance Zin of the transistor Q1. Thus, by providing the capacitive element 56, it is possible to reduce the variation in impedance Zin in the amplifier circuit, thereby improving the characteristics.

As illustrated in FIG. 1 and FIG. 2, the semiconductor device 100 includes the output terminal Tout that outputs the high-frequency signal amplified by the semiconductor chip 30. As illustrated in FIG. 1 and FIG. 3, the source electrode 12 is electrically connected to a reference potential, and the drain electrode 14 is electrically connected to the output terminal Tout. In this case, the efficiency and other characteristics vary in accordance with the input impedance Zin of the transistor Q1. Thus, by providing the capacitive element 56, the variation in impedance Zin can be reduced, thereby improving the characteristics.

As illustrated in FIG. 8, when the Smith chart is expressed in polar coordinates in which the phase (angle of polar coordinates) at the open-circuit position is set to zero degrees and the angle increases counterclockwise, the phase of the average impedance Zin of the units 22 as viewed from the gate pad 17 to the matching circuit 52 at the frequency 2f0, which is twice the center frequency f0, is within the range of −150 degrees to −15 degrees, inclusive. This can improve the efficiency of the semiconductor device. In addition, when the phase of the impedance Zin at the frequency 2f0 is from −150 degrees to −30 degrees, inclusive, the amplitude of the impedance Zin at the frequency 2f0 can be increased by shunt-connecting the capacitive element 56. Thus, the characteristics can be improved. The phase of the impedance Zin at the frequency 2f0 may be −135 degrees to −45 degrees, inclusive. The amplitude of the impedance Zin at the frequency 2f0 can be 0.7 or more when the center SC is set to zero and the outer circumference OC is set to one. Accordingly, the amplitude of the impedance Zin at the frequency 2f0 can be increased by shunt-connecting the capacitive element 56. When the amplitude of the impedance Zin at the frequency 2f0 is made close to one, the efficiency of the semiconductor device is increased.

In addition, as illustrated in FIG. 8, the first impedance as viewed from the gate electrode 16 of the first unit close to the center 50C to the matching circuit 52 when the capacitive element 56 is not provided has a smaller radius vector magnitude in polar coordinates than the second impedance as viewed from the gate electrode 16 of the second unit close to the edge 50E to the matching circuit 54 when the capacitive element 56 is not provided. In such a case, by providing the capacitive element 56 in the first unit, the variation in impedance Zin can be reduced, thereby improving the characteristics.

When the center frequency f0 becomes high, the matching circuit 52 behaves as a distributed constant. When the power of the output high-frequency signal is large, the gate pad 17 becomes long in the Y-axis direction, and the number of bonding wires 42 increases. In addition, the number of units 20 becomes large. From these viewpoints, the frequency of the high-frequency signal may be 0.5 GHz or more, and the power may be 50 W or more. The number of bonding wires 42 may be five or more. The number of the units 20 may be 10 or more.

It should be understood that the embodiments disclosed herein are merely illustrative and non-restrictive in all respects. The scope of the present disclosure is defined by the claims, not in the sense described above, and is intended to include all modifications within the scope and meaning equivalent to the claims.

What is claimed is:

1. A semiconductor device comprising:
a semiconductor chip including
a substrate,
a plurality of units arranged in an array direction, each of the plurality of units including a unit FET having a gate electrode, a source electrode, and a drain electrode provided on the substrate, and
a gate pad to which the gate electrode of each of the plurality of units is electrically connected, the gate pad extending in the array direction and being provided on the substrate;
an input terminal to which a high-frequency signal is input; and
a matching circuit including a plurality of bonding wires electrically connected between the input terminal and the gate pad, each of the plurality of bonding wires having a first end bonded to a respective one of a plurality of regions arranged in the array direction in the gate pad,
wherein the plurality of units include a first unit and a second unit, and the first unit is closer to a center of the plurality of units in the array direction than the second unit is,
wherein the first unit includes a first capacitive element electrically connected between the gate pad and a reference potential, and
wherein the second unit includes no capacitive element electrically connected between the gate pad and the reference potential, or includes a second capacitive element electrically connected between the gate pad and the reference potential and having a capacitance value smaller than a capacitance value of the first capacitive element.

2. The semiconductor device according to claim 1,
wherein the first unit is a unit closest to the center among the plurality of units, and
the second unit is a unit farthest from the center among the plurality of units.

3. The semiconductor device according to claim 2,
wherein the first capacitive element has a largest capacitance value among capacitive elements electrically connected between the gate pad and the reference potential in the plurality of units.

4. The semiconductor device according to claim 2,
wherein the second unit includes no capacitive element electrically connected between the gate pad and the reference potential.

5. The semiconductor device according to claim 1,
wherein the plurality of units includes a third unit located between the first unit and the second unit,
wherein the third unit includes a third capacitive element electrically connected between the gate pad and the reference potential and having a capacitance value smaller than the capacitance value of the first capacitive element, and
wherein the third capacitive element has a capacitance value larger than the capacitance value of the second capacitive element when the second unit includes the second capacitive element.

6. The semiconductor device according to claim 1,
wherein the first capacitive element has an electrode electrically connected to the gate pad and provided on the source electrode, with an insulating layer interposed between the source electrode and the electrode.

7. The semiconductor device according to claim 1, further comprising:
a base on which the semiconductor chip is mounted,
wherein the matching circuit is mounted on the base, and includes a dielectric substrate, an electrode provided on the dielectric substrate and extending in the array direction, and a component mounted on the base, and
wherein a second end of each of the plurality of bonding wires is bonded to a respective one of a plurality of regions arranged in the array direction in the electrode.

8. The semiconductor device according to claim 1,
wherein the semiconductor chip is configured to amplify the high-frequency signal input to the gate pad.

9. The semiconductor device according to claim 8, further comprising:
an output terminal configured to output the high-frequency signal amplified by the semiconductor chip,
wherein the source electrode is electrically connected to the reference potential, and the drain electrode is electrically connected to the output terminal.

10. The semiconductor device according to claim 1,
wherein an angle of impedance as viewed from the gate electrode to the matching circuit at a frequency that is twice a center frequency of an operating band is within a range of −150 degrees to −15 degrees, inclusive, when a Smith chart is expressed in polar coordinates in which an angle at an open-circuit position is set to zero degrees and angle increases counterclockwise.

11. The semiconductor device according to claim 10,
wherein a first impedance as viewed from the gate electrode of the first unit to the matching circuit when the first capacitive element is not provided has a smaller radius vector magnitude in the polar coordinates than a second impedance as viewed from the gate electrode of the second unit to the matching circuit when the second capacitive element is not provided.

12. A semiconductor device comprising:
a substrate;
a plurality of units arranged in an array direction on the substrate, each of the plurality of units including a unit FET having a gate electrode, a source electrode, and a drain electrode; and
a gate pad to which the gate electrode of each of the plurality of units is connected, the gate pad extending in the array direction and being provided on the substrate,
wherein the plurality of units include a first unit and a second unit, and the first unit is closer to a center of the plurality of units in the array direction than the second unit is,
wherein the first unit includes a first capacitive element electrically connected between the gate pad and a reference potential, and
wherein the second unit includes no capacitive element electrically connected between the gate pad and the reference potential, or includes a second capacitive element electrically connected between the gate pad and the reference potential and having a capacitance value smaller than a capacitance value of the first capacitive element.
